(19) United States
(12) Patent Application Publication
(10) Pub. No.: US 2026/0082906 A1
(43) Pub. Date: Mar. 19, 2026

(54) INTEGRATED CIRCUIT DEVICES WITH COOLING PLATES

(71) Applicant: Advanced Micro Devices, Inc., Santa Clara, CA (US)

(72) Inventors: Zean XIA, Shanghai (CN); Xiaoxu LI, Shanghai (CN)

(21) Appl. No.: 18/886,989

(22) Filed: Sep. 16, 2024

(51) Int. Cl. H01L 23/367; H01L 23/373; H01L 23/467; H01L 25/065; H05K 1/02; H10B 80/00

(52) U.S. Cl. CPC H10W 40/22; H05K 1/0203; H10B 80/00; H10W 40/226; H10W 40/258; H10W 40/43; H10W 90/00; H05K 2201/064; H05K 2201/066; H05K 2201/10159; H05K 2201/10522

(57) ABSTRACT

Examples herein describe integrated circuit (IC) devices with cooling plates. An IC device includes a circuit board and an IC die mounted on a first side of the circuit board. A thermally conductive plate is disposed over the first side of the circuit board. Thermal interface material is disposed between the IC die and the thermally conductive plate. The IC device includes fins having a first end in contact with a side of the thermally conductive plate that contacts the thermal interface material and a second end that extends beyond a second side of the circuit board.

### TECHNICAL FIELD

Examples of the present disclosure generally relate to integrated circuit (IC) devices, and more specifically, to IC devices having cooling plates.

### BACKGROUND

Demand for increased memory and processing capacity in cloud computing and artificial intelligence (AI) applications has caused a corresponding increase in the speed/performance of newly developed integrated circuit (IC) processors and memory components. The increased speed of the memory components requires these components to consume more power which increases heat generation. However, system form factor limitations and spacing limitations of standards have not changed to compensate for the additional heat generated by the faster memory components. In some cases, the lack of change is because the spacing limitations are specified by widely adopted and implemented standards. As a result, the high-speed memory components are subjected to excessive heat during operation which can cause instability, reduced performance, and accelerated degradation of the components.

### SUMMARY

Integrated circuit (IC) devices with cooling plates are described in some embodiments. In various embodiments, an IC device includes a circuit board and an IC die mounted on a first side of the circuit board. A thermally conductive plate is disposed over the first side of the circuit board. Thermal interface material is disposed between the IC die and the thermally conductive plate. Fins have a first end in contact with a side of the thermally conductive plate that contacts the thermal interface material. The fins have a second end that extends beyond a second side of the circuit board.

An integrated circuit (IC) assembly is described in some embodiments. In one or more embodiments, the IC assembly includes a printed circuit board (PCB). A first IC die and a second IC die are mounted on a first side of the PCB. First thermal interface material is disposed between the first IC die and a thermally conductive plate. Second thermal interface material is disposed between the second IC die and the thermally conductive plate. A heat sink is disposed over a second side of the PCB. Fins are fixed to the thermally conductive plate and extend between a surface of the thermally conductive plate and the heat sink.

A method is described in some embodiments. The method includes disposing a printed circuit board (PCB) that includes and integrated circuit (IC) die between a thermally conductive plate and a heat sink. The thermally conductive plate has fins that extend from a first side of the PCB beyond a second side of the PCB. The heat sink has additional fins. An end of the fins that extends beyond the second side of the PCB is aligned with the additional fins.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1A illustrates a plan view of a first side of a thermally conductive plate, according to some embodiments.

FIG. 1B illustrates a plan view of a first side of a printed circuit board (PCB), according to some embodiments.

FIG. 2A illustrates a side view of an assembly that includes a printed circuit board (PCB) and a thermally conductive plate, according to some embodiments.

FIG. 2B illustrates a side view of an assembled thermally conductive plate and printed circuit board (PCB), according to some embodiments.

FIG. 2C illustrates a plan view of an assembled thermally conductive plate and printed circuit board (PCB), according to some embodiments.

FIG. 3A illustrates a plan view of a first side of a heat sink, according to some embodiments.

FIG. 3B illustrates a side view of an assembly that includes an assembled thermally conductive plate and printed circuit board (PCB) and a heat sink, according to some embodiments.

FIG. 3C is a plan view of an assembled thermally conductive plate, printed circuit board (PCB), and heat sink according to some embodiments.

FIG. 4A illustrates a plan view of air intake fans, according to some embodiments.

FIG. 4B illustrates a plan view of an assembled thermally conductive plate, printed circuit board (PCB), heat sink, and air intake fans, according to some embodiments.

FIG. 4C illustrates a plan view of circulating air, according to some embodiments.

FIG. 5 illustrates examples of fins, according to some embodiments.

FIG. 6 is a flow diagram depicting a method for disposing a printed circuit board (PCB) between a thermally conductive plate and a heat sink, according to some embodiments.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

The speed of newly developed integrated circuit (IC) processors and memory components has increased substantially due to recent demand for increased memory and processing capacity in artificial intelligence (AI) applications. To facilitate this increase in speed, the memory components consume more power which generates more heat during operation of the components. However, system form factor limitations and spacing limitations of standards (e.g., the Peripheral Component Interconnect Express (PCIe) standard) have not changed to compensate for the additional heat generated by the faster memory components. For example, air flow in conventional “clamshell” memory packaging is constrained by PCIe spacing limitations. The lack of change may be partly because the spacing limitations are specified by widely adopted and implemented standards. Regardless, the high-speed memory components are subjected to excessive heat during operation which can cause instability and diminish performance of the memory components.

In order to cool an IC device, the IC device includes a printed circuit board (PCB) and an IC die mounted on a first side of the PCB (e.g., a bottom side), where a thermally conductive plate is disposed over the first side of the PCB. Thermal interface material is disposed between the IC die and the thermally conductive plate. Fins have a first end in contact with a side of the thermally conductive plate that contacts the thermal interface material. The fins have a second end that extends beyond a second side of the PCB (e.g., a primary side).

In certain embodiments, the fins are fabricated from a material that includes a thermal conductor such as aluminum. In some embodiments, the fins can include apertures or openings (e.g., to increase the surface area of the fins). In other embodiments, the fins may not include apertures or openings (e.g. to avoid introducing turbulence to flowing air). A heat sink that includes additional fins is disposed over a second side of the PCB. The additional fins may facilitate active cooling of the PCB. In one or more embodiments, the fins extend between the thermally conductive plate and the additional fins of the heat sink.

One or more air intake fans are disposed over the additional fins of the heat sink. The air intake fans circulate air into the additional fins of the heat sink and heat generated by circuitry disposed on the IC die is transferred to the air circulated by the air intake fans. For example, the air circulated by the air intake fans actively cools the circuitry by decreasing an operating temperature of the circuitry. As the air intake fans continue to circulate new air into the additional fins of the heat sink, the new air displaces the air that absorbed the heat from the circuitry which is circulated out through the fins.

The fins improve the mechanism for cooling the circuitry by converting a passive cooling system into an active cooling system. Based on simulation results, the active cooling system is capable of decreasing operating temperatures of the circuitry by about 4.75 to 8.25 percent relative to a passive cooling system. The fins can be added to the thermally conductive plate with minimal or no modification to the layout of the circuitry. Additionally, the improved cooling of the circuitry can be accomplished without consideration of potential spacing limitations (e.g., above or below the circuitry).

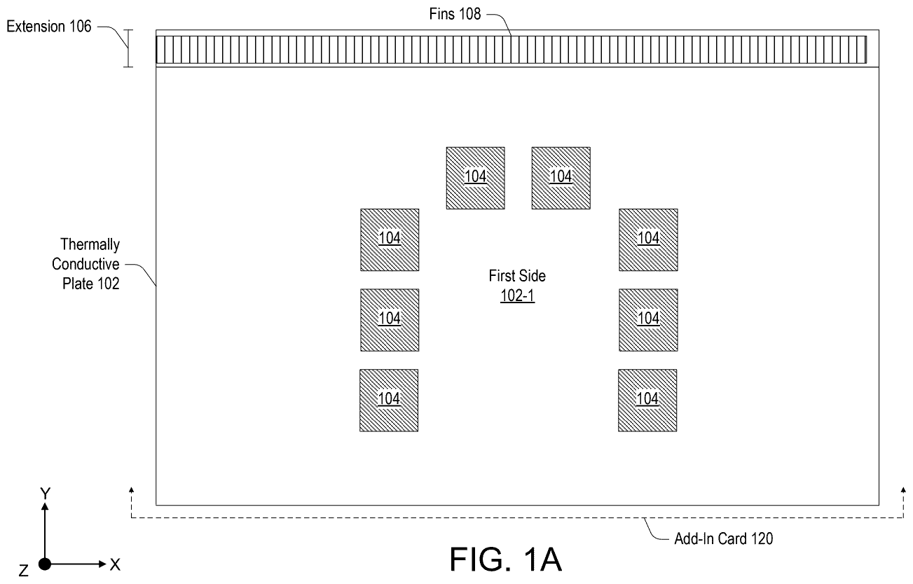

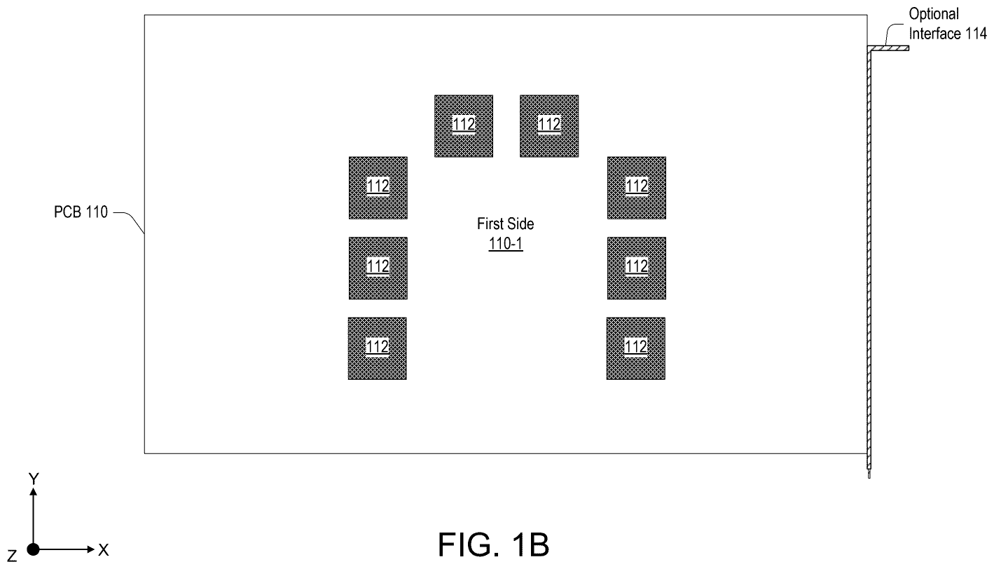

FIG. 1A illustrates a plan view of a first side 102-1 of a thermally conductive plate 102, according to some embodiments. The thermally conductive plate 102 is part of an integrated circuit (IC) assembly in some examples. The thermally conductive plate 102 comprises one or more materials having relatively high thermal conductivity such as copper, aluminum, graphite, graphene, and/or another material having relatively high thermal conductivity.

As shown in FIG. 1A, the first side 102-1 of the thermally conductive plate 102 includes thermal interface material portions 104 configured to interface with ICs. Like the thermally conductive plate 102, the thermal interface material portions 104 comprise one or more materials having relatively high thermal conductivity such as graphite, graphene, and/or another material having relatively high thermal conductivity. Although eight thermal interface material portions 104 are shown, it is to be appreciated that, in some embodiments, the thermally conductive plate 102 includes more than eight thermal interface material portions 104 or less than eight thermal interface material portions 104.

The thermally conductive plate 102 is illustrated as extending in the X-direction and the Y-direction (all directions shown in lower left of FIG. 1A). In some embodiments, form factors requirements or spacing limitations restrict expansion into space above or below the thermally conductive plate 102 in the Z-direction (e.g., within the bounds of the X, Y dimensions of the thermally conductive plate 102). In an example in which the thermally conductive plate 102 is included in an add-in card 120 that complies with the Peripheral Component Interconnect Express (PCIe) standard, a maximum height of a component extending in the Z-direction relative to the thermally conductive plate 102 may be about 2.67 millimeters. However, spacing limitations in the Y-direction may be less restricted in this example. In one or more embodiments, the thermally conductive plate 102 includes an extension 106 in the Y-direction of about 5 millimeters and a component may extend in at least one of the positive Z-direction or the negative Z-direction relative to the extension 106.

In some embodiments, fins 108 are included within the extension 106 and the fins 108 extend in the Z-direction relative to the extension 106 of the thermally conductive plate 102. In other embodiments, the fins 108 may be included outside of the extension 106 or the thermally conductive plate 102 may be fabricated without the extension 106 in the Y-direction. In certain embodiments, the thermally conductive plate 102 is fabricated with the extension 106 in the X-direction and the fins 108 may or may not be included within the extension 106 in the X-direction.

In some examples, the fins 108 comprise one or more materials having relatively high thermal conductivity such as copper, aluminum, graphite, graphene, and/or another material having relatively high thermal conductivity. In one or more embodiments, the fins 108 include apertures which increase a surface area of the fins 108 compared to fins without apertures. The fins 108 can be manufactured separately from the thermally conductive plate 102 and then fixed to the thermally conductive plate 102 by a weld, a solder, an epoxy, an adhesive, a press fit, or another type of coupling. The fins 108 can also be manufactured concurrently with the thermally conductive plate 102 by stamping, extrusion, additive manufacturing, conventional machining, or another manufacturing technique.

FIG. 1B illustrates a plan view of a first side 110-1 of a printed circuit board (PCB) 110, according to some embodiments. The PCB 110 is part of the IC assembly in some examples. The first side 110-1 of the PCB 110 is illustrated to include IC dies 112. The IC dies 112 can include circuitry such as memory circuitry, processor circuitry, and/or other circuitry. In some embodiments, the IC dies 112 include synchronous dynamic random-access memory (SDRAM) ICs. In the illustrated example of FIG. 1B, the PCB 110 includes eight IC dies 112.

The thermal interface material portions 104 of the thermally conductive plate 102 are configured to interface with the IC dies 112 such that heat generated by the circuitry disposed on the IC dies 112 is transferred to the thermal interface material portions 104. Although eight IC dies 112 are shown in FIG. 1B, it is to be appreciated that, in some embodiments, the PCB 110 includes more than eight IC dies 112 or less than eight IC dies 112. As shown in the plan view of FIG. 1B, the PCB 110 includes an optional interface 114. The optional interface 114 is configured to couple the thermally conductive plate 102 and the PCB 110 in some examples.

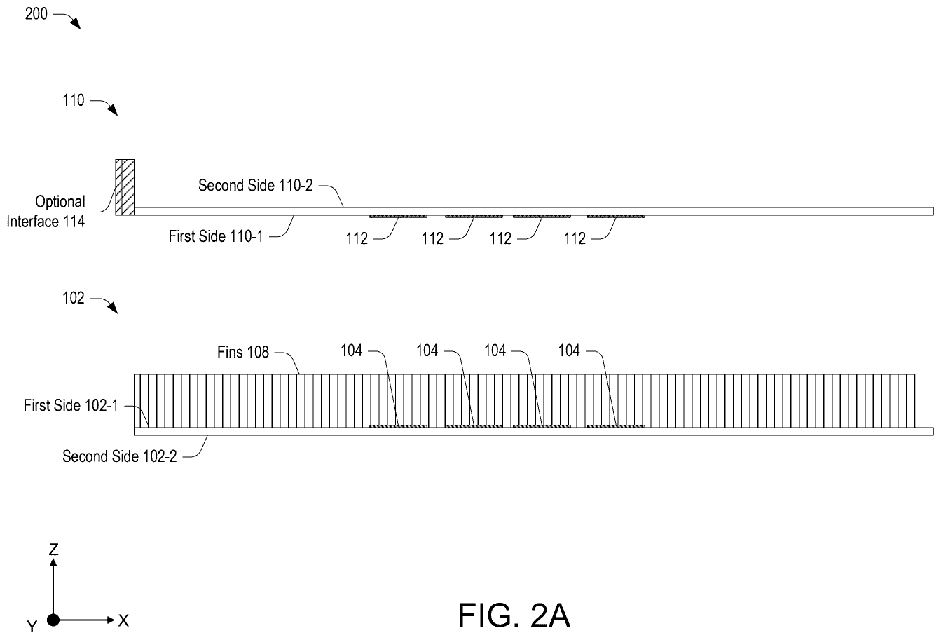

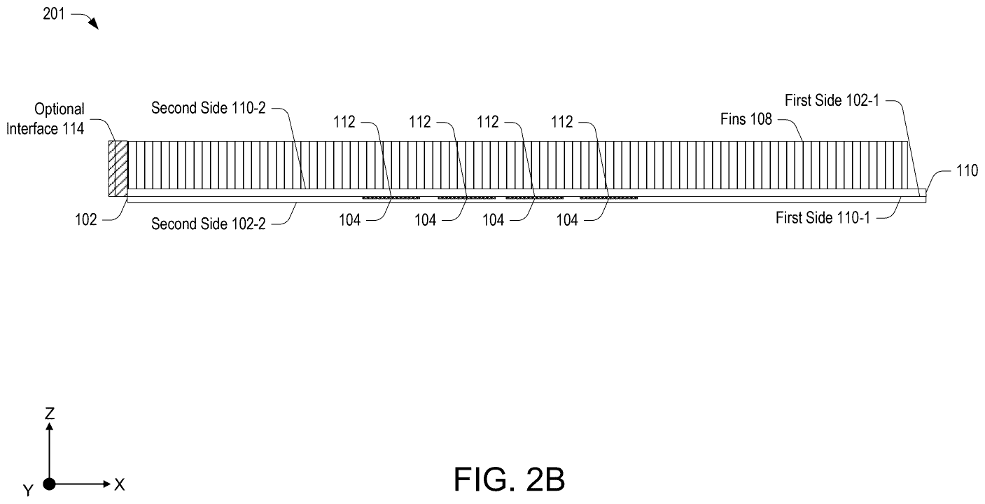

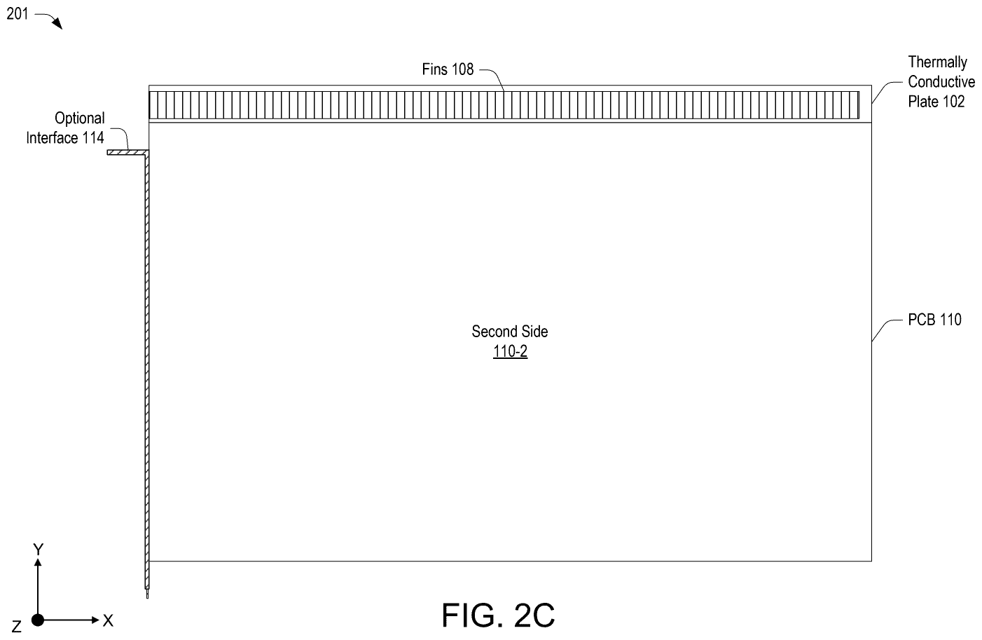

FIG. 2A illustrates a side view of an assembly 200 that includes a printed circuit board (PCB) 110 and a thermally conductive plate 102, according to some embodiments. As shown, the PCB 110 and the thermally conductive plate 102 are oriented such that the first side 110-1 of the PCB 110 faces the first side 102-1 of the thermally conductive plate 102. Notably, the IC dies 112 are aligned with the thermal interface material portions 104 in the Z-direction in the assembly 200. In some embodiments, the fins 108 are aligned with the optional interface 114 in the Y-direction.

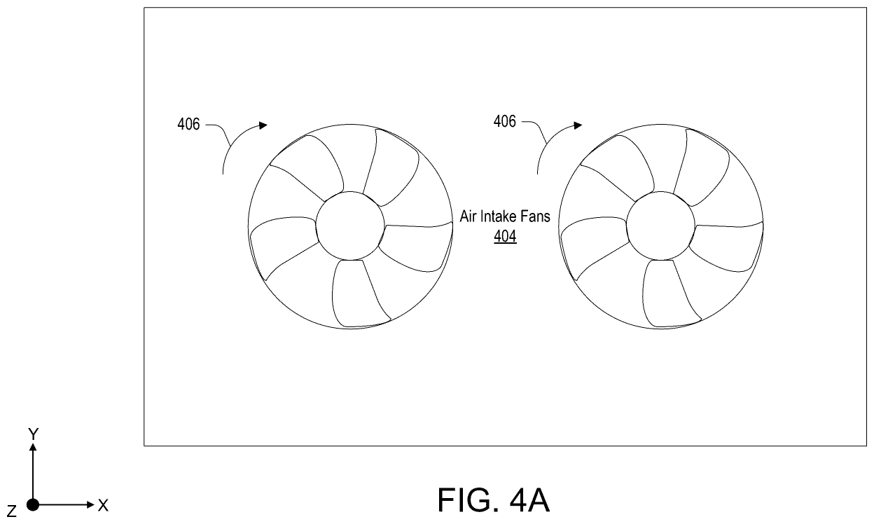

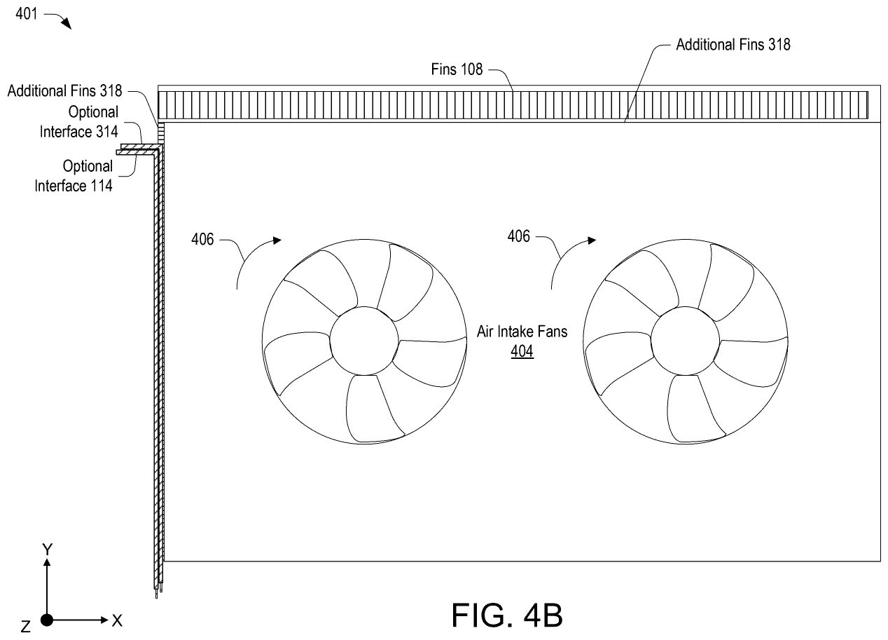

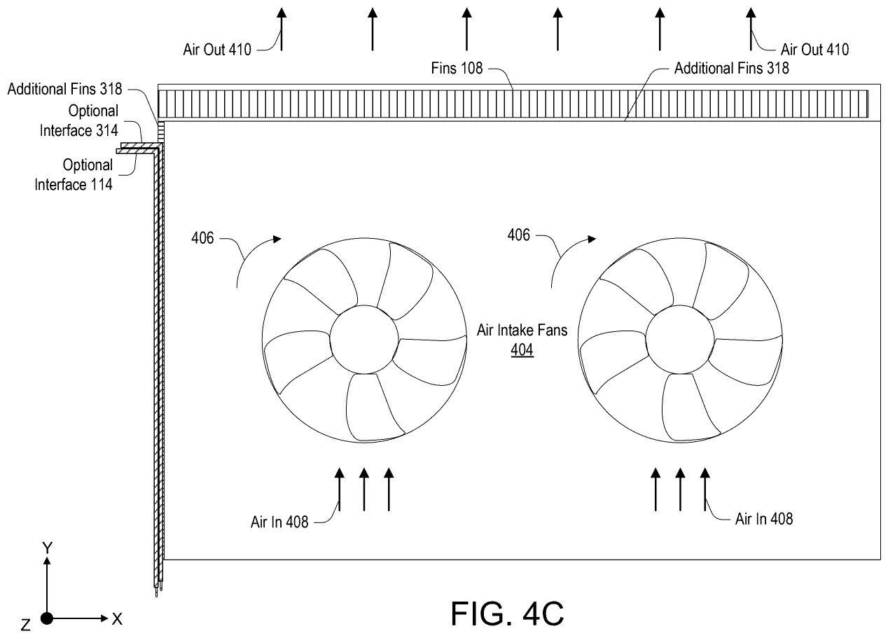

FIG. 2B illustrates a side view of an assembled 201 thermally conductive plate 102 and printed circuit board (PCB) 110, according to some embodiments. As shown in FIG. 2B, the second side 102-2 of the thermally conductive plate 102 faces away from a second side 110-2 of the PCB 110 in the Z-direction. In the side view, the thermally conductive plate 102 is disposed over the PCB 110 such that the first side 102-1 of the thermally conductive plate 102 interfaces with the first side 110-1 of the PCB 110 and each of the thermal interface material portions 104 interfaces with a corresponding one of the IC dies 112. Since the thermal interface material portions 104 interface with the IC dies 112, the thermal interface material portions 104 are configured to transfer heat generated by the circuitry disposed on the IC dies 112 to the thermally conductive plate 102 which passively cools the circuitry disposed on the IC dies 112. In some embodiments, the heat transferred to the thermally conductive plate 102 from the thermal interface material portions 104 can be transferred to circulated air to actively cool the thermally conductive plate 102 and/or the circuitry disposed on the IC dies 112 as described with respect to FIGS. 4A-4C.

FIG. 2C illustrates a plan view of an assembled 201 thermally conductive plate 102 and printed circuit board (PCB) 110, according to some embodiments. In the plan view, the fins 108 are disposed above the optional interface 114 in the Y-direction. The fins 108 extend beyond the second side 110-2 of the PCB 110 in the Z-direction. In some embodiments, the PCB 110 is disposed over a portion of the thermally conductive plate 102 that does not include the fins 108 such that air can be circulated through the fins 108 in the Y-direction.

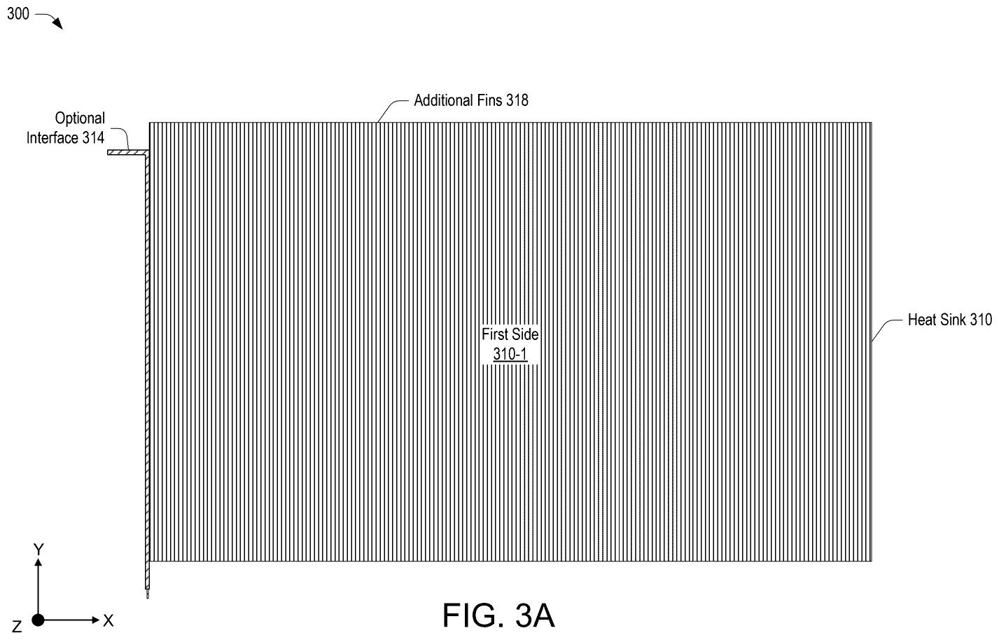

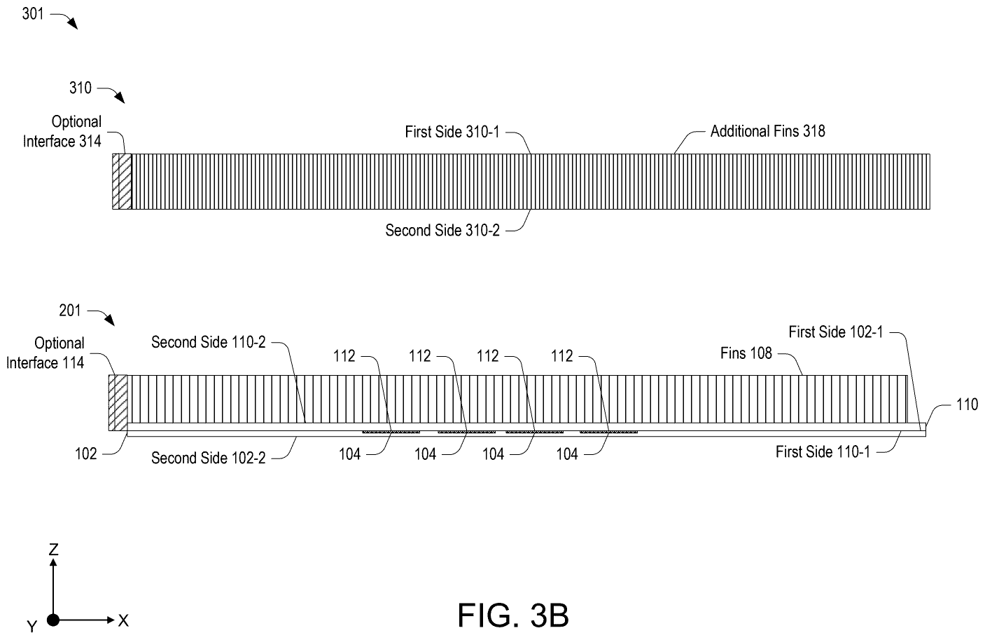

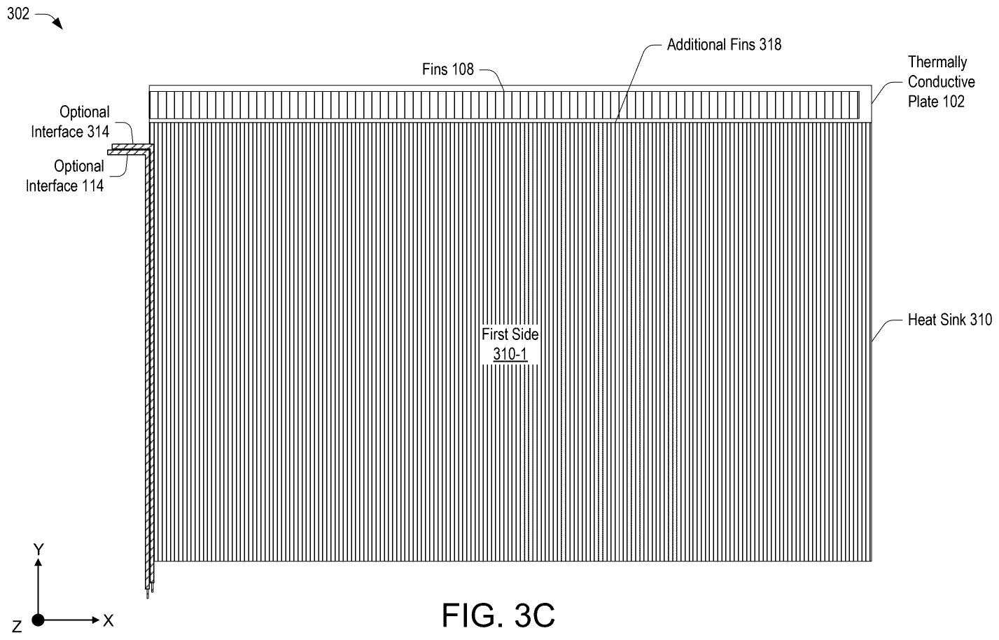

FIG. 3A illustrates a plan view of a first side 310-1 of a heat sink 310, according to some embodiments. The heat sink 310 comprises one or more materials having relatively high thermal conductivity such as copper, aluminum, graphite, graphene, and/or another material having relatively high thermal conductivity. As shown in FIG. 3A, the heat sink 310 includes an optional interface 314 and additional fins 318. For example, the additional fins 318 increase a surface area of the heat sink 310 and the additional fins 318 include apertures which further increase the surface area of the heat sink 310. The apertures of the additional fins 318 also facilitate circulation of air through the additional fins 318 which can be used to actively cool the thermally conductive plate 102 and/or the circuitry disposed on the IC dies 112 as described relative to FIGS. 4A-4C.

FIG. 3B illustrates a side view of an assembly 301 that includes an assembled 201 thermally conductive plate 102 and printed circuit board (PCB) 110 and a heat sink 310, according to some embodiments. In the side view, a second side 310-2 of the heat sink 310 is facing the second side 110-2 of the PCB 110. The optional interface 314 is offset from the optional interface 114 such that a portion of the optional interface 314 aligns/interfaces with a portion of the optional interface 114 in the Z-direction.

FIG. 3C is a plan view of an assembled 302 thermally conductive plate 102, printed circuit board (PCB) 110, and heat sink 310 according to some embodiments. As shown, the additional fins 318 extend in the Y-direction and the X-direction and are perpendicular (normal) to the fins 108 extending in the Z-direction. The first side 310-1 of the heat sink 310 is facing up in the Z-direction, and the optional interface 314 interfaces with the optional interface 114. In some embodiments, the first and optional interfaces 114, 314 are configured to couple the heat sink 310 to the PCB 110 which is also coupled to the thermally conductive plate 102. Accordingly, the heat sink 310 is coupled to the thermally conductive plate 102 via the PCB 110.

FIG. 4A illustrates a plan view of air intake fans 404, according to some embodiments. The air intake fans 404 are configured to rotate in a direction 406 to circulate air from a first side of the air intake fans 404 to a second side of the air intake fans 404. Although the plan view illustrates two air intake fans 404, it is to be appreciated that, in some embodiments, the air intake fans 404 include more than two air intake fans 404 or a single air intake fan 404.

FIG. 4B illustrates a plan view of an assembled 401 thermally conductive plate 102, printed circuit board (PCB) 110, heat sink 310, and air intake fans 404, according to some embodiments. The air intake fans 404 are disposed over the first side 310-1 of the heat sink 310 between the fins 108 and the optional interface 314. In some embodiments, the air intake fans 404 are coupled to the optional interface 314 which is coupled to the optional interface 114. Since the first and optional interfaces 114, 314 couple the heat sink 310 to the PCB 110 and because the thermally conductive plate 102 is coupled to the PCB 110, the air intake fans 404 may be coupled to the heat sink 310 and the PCB 110 via the first and optional interfaces 114, 314, and the air intake fans 404 can be indirectly coupled to the thermally conductive plate 102 via the PCB 110.

FIG. 4C illustrates a plan view of circulating air, according to some embodiments. As shown, rotating the air intake fans 404 in the direction 406 generates a negative pressure or a vacuum above the air intake fans 404. The negative pressure circulates air in 408 through the air intake fans 404 and the additional fins 318 of the heat sink 310. Rotating the air intake fans 404 in the direction 406 also generates a positive pressure below the air intake fans 404. The positive pressure circulates the air in 408 over the PCB 110 such that heat generated by the circuitry disposed on the IC dies 112 is transferred to the air in 408 which cools the circuitry disposed on the IC dies 112. After the heat from the circuitry disposed on the IC dies 112 is transferred to the air in 408, the positive pressure generated by the air intake fans 404 circulates the air in 408 through the fins 108 as air out 410. Notably, as the air out 410 which includes the heat transferred from the circuitry disposed on the IC dies 112 is circulated out through the fins 108, the negative pressure above the air intake fans 404 circulates new air in 408 through the additional fins 318 of the heat sink 310. Additional heat generated by the circuitry disposed on the IC dies 112 is transferred to the new air in 408 which is circulated out through the fins 108 as new air out 410. The continued circulation of air in 408 and air out 410 actively cools the circuitry disposed on the IC dies 112 and decreases the operating temperatures of the circuitry (e.g., memory circuitry) disposed on the IC dies 112 in a range of about 4.75 to 8.25 percent compared to a conventional passive IC device cooling system which does not include the fins 108 added to the thermally conductive plate 102 that facilitate active cooling of the circuitry disposed on the IC dies 112.

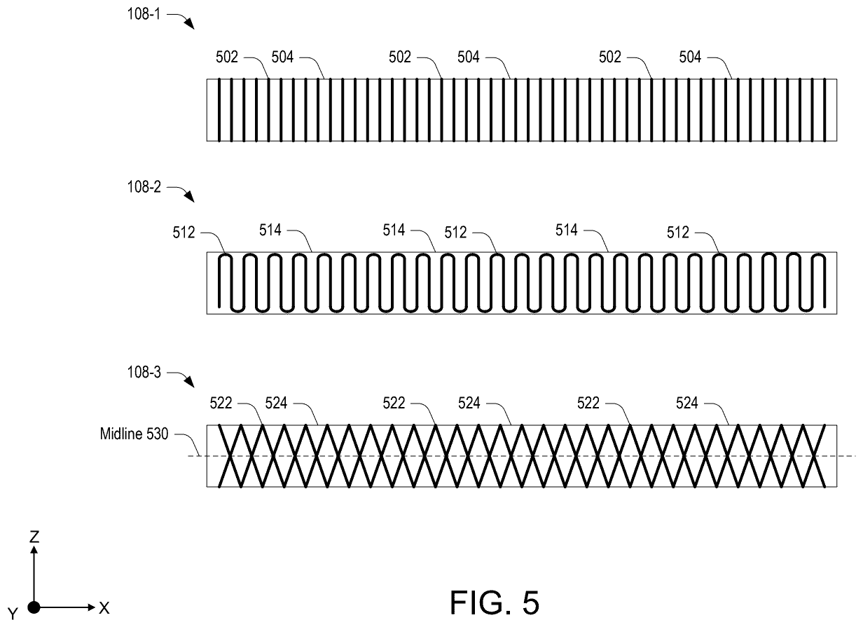

FIG. 5 illustrates examples of fins 108-1, 108-2, 108-3, according to some embodiments. Each of the examples of the fins 108-1, 108-2, 108-3 comprise one or more materials having relatively high thermal conductivity such as copper, aluminum, graphite, graphene, and/or another material having relatively high thermal conductivity. The fins 108-1 include discrete solid portions 502 that extend vertically in the Z-direction which comprise the one or more materials having relatively high thermal conductivity. In some embodiments, the fins 108-1 also include apertures 504 in between the discrete solid portions 502. In other embodiments, the fins 108-1 may not include the apertures 504 such that the discrete solid portions 502 include a single continuous solid portion.

The fins 108-2 include continuous solid portions 512 which comprise the one or more materials having relatively high thermal conductivity. In some embodiment, the fins 108-2 also include apertures 514 interspaced between vertical portions of the continuous solid portions 512. Unlike the apertures 504 of the fins 108-1 that extend from a top to a bottom of the fins 108-1, the apertures 514 of the fins 108-2 extend partially between a top and a bottom of the fins 108-2. In one or more embodiments, the fins 108-2 may not include the apertures 504 (e.g., to avoid introducing turbulence to flowing air).

The fins 108-3 also include continuous solid portions 522 which comprise the one or more materials having relatively high thermal conductivity. The continuous solid portions 522 extend in both the Z-direction and the X-direction. In various embodiments, the fins 108-3 include apertures 524 which are illustrated as extending from a top of the fins 108-3 to a midline 530 of the fins 108-3 and also extending from a bottom of the fins 108-3 to the midline 530 of the fins 108-3. In some embodiments, the fins 108-3 may not include the apertures 524.

It is to be appreciated that the examples of the fins 108-1, 108-2, 108-3 are not exhaustive embodiments of the fins 108 which can include a variety of different dimensions and geometries of both solid portions and apertures. In some embodiments, dimensions and geometries of features included in the fins 108 may be based on particular memory cooling implementations. By way of example, some embodiments of the fins 108 may have cross-sections which include more solid portions than apertures while other embodiments of the fins 108 can have cross-sections that include more apertures than solid portions. By way of further example, some embodiments of the fins 108 may have cross-sections which do not include apertures (e.g., to avoid introducing turbulence to flowing air).

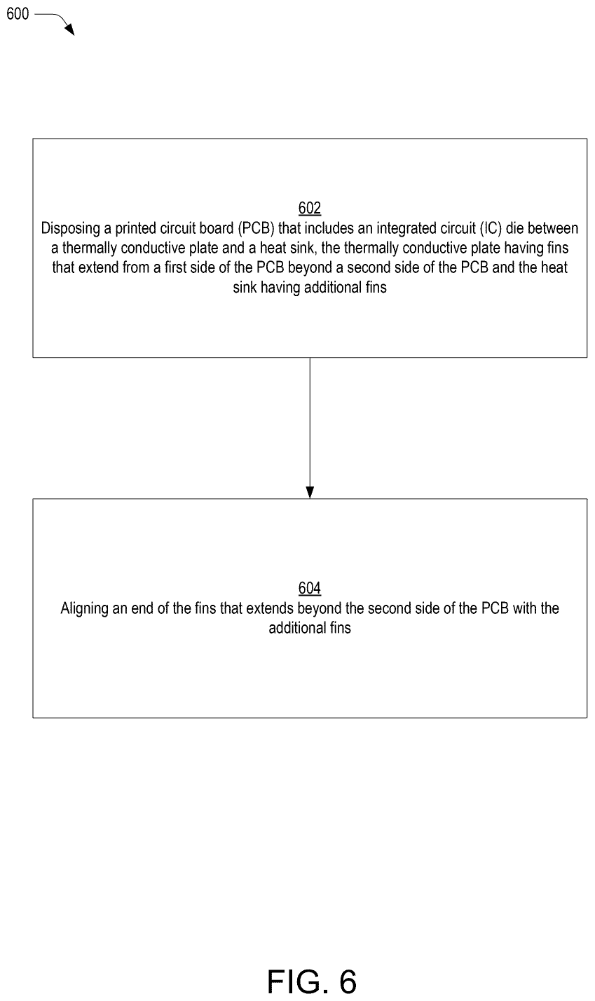

FIG. 6 is a flow diagram depicting a method 600 for disposing a printed circuit board (PCB) 110 between a thermally conductive plate 102 and a heat sink 310, according to some embodiments. At operation 602, a printed circuit board (PCB) that includes an IC die is disposed between a thermally conductive plate and a heat sink, the thermally conductive plate has fins that extend from a first side of the PCB beyond a second side of the PCB and the heat sink has additional fins. In some embodiments, the PCB 110 includes the IC dies 112 and the PCB 110 is disposed between the thermally conductive plate 102 and the heat sink 310 such that the fins 108 extend from the first side 110-1 of the PCB 110 beyond the second side 110-2 of the PCB 110.

At operation 604, an end of the fins that extends beyond the second side of the PCB is aligned with the additional fins. In one or more embodiments, the second end of the fins 108 that extends beyond the second side 110-2 of the PCB 110 is aligned with the additional fins 318 (e.g., the second end of the fins 108 interfaces with the additional fins 318).

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

While the foregoing is directed to specific examples, other and further examples may be devised without departing from the basic scope thereof, and the scope thereof is determined by the claims that follow.

What is claimed is:

1. An integrated circuit (IC) device comprising:
a circuit board;
an IC die mounted on a first side of the circuit board;
a thermally conductive plate disposed over the first side of the circuit board;
thermal interface material disposed between the IC die and the thermally conductive plate; and
fins having a first end in contact with a side of the thermally conductive plate that contacts the thermal interface material and a second end that extends beyond a second side of the circuit board.

2. The IC device of claim 1, wherein the first end of the fins is fixed to the side of the thermally conductive plate that contacts the thermal interface material.

3. The IC device of claim 1, wherein the fins include apertures.

4. The IC device of claim 1, wherein the fins are fabricated from aluminum.

5. The IC device of claim 1, further comprising memory circuitry disposed on the IC die.

6. The IC device of claim 5, wherein the memory circuitry comprises synchronous dynamic random-access memory (SDRAM).

7. The IC device of claim 1, further comprising:
a heat sink disposed over the second side of the circuit board; and
additional fins of the heat sink.

8. The IC device of claim 7, wherein the second end of the fins interfaces with the additional fins of the heat sink.

9. The IC device of claim 8, further comprising an air intake fan configured to circulate air through the additional fins of the heat sink.

10. The IC device of claim 9, wherein the air circulated through the additional fins of the heat sink flows out through the fins.

11. An integrated circuit (IC) assembly comprising:
a printed circuit board (PCB);
a first IC die and a second IC die mounted on a first side of the PCB;
first thermal interface material disposed between the first IC die and a thermally conductive plate;
second thermal interface material disposed between the second IC die and the thermally conductive plate;
a heat sink disposed over a second side of the PCB; and
fins fixed to the thermally conductive plate and extending between a surface of the thermally conductive plate and the heat sink.

12. The IC assembly of claim 11, wherein memory circuitry disposed on the first IC die comprises synchronous dynamic random-access memory (SDRAM).

13. The IC assembly of claim 11, further comprising an air intake fan configured to circulate air into the heat sink and out from the fins.

14. The IC assembly of claim 13, wherein the air circulated into the heat sink and out from the fins is configured to decrease an operating temperature of an IC device disposed on the first IC die.

15. The IC assembly of claim 11, wherein the fins are fabricated from aluminum.

16. The IC assembly of claim 11, wherein the PCB is part of a Peripheral Component Interconnect Express (PCIe) card.

17. A method comprising:
disposing a printed circuit board (PCB) that includes an integrated circuit (IC) die between a thermally conductive plate and a heat sink, the thermally conductive plate having fins that extend from a first side of the PCB beyond a second side of the PCB and the heat sink having additional fins; and
aligning an end of the fins that extends beyond the second side of the PCB with the additional fins.

18. The method of claim 17, wherein memory circuitry disposed on the IC die includes synchronous dynamic random-access memory (SDRAM).

19. The method of claim 17, wherein the fins are normal to the additional fins.

20. The method of claim 17, wherein the fins are fabricated from aluminum.
